(19) United States
(12) Patent Application Publication
(10) Pub. No.: US 2007/0291325 A1
(43) Pub. Date: Dec. 20, 2007

(54) Combined Image Pickup-Display Device

(76) Inventors: Yoshiaki Toyota, Hachioji (JP); Naohiro Furukawa, Tachikawa (JP); Hisashi Ikeda, Kunitachi (JP); Takeo Shiba, Kodaira (JP); Mieko Matsumura, Kokubunji (JP)

Correspondence Address: REED SMITH LLP, 3110 FAIRVIEW PARK DRIVE, SUITE 1400, FALLS CHURCH, VA, 22042, US

(21) Appl. No.: 11/578,543

(22) PCT Filed: Apr. 19, 2004
(86) PCT No.: PCT/JP04/05539

§ 371 Date: Jun. 4, 2007

(51) Int. Cl. H04N 1/04

(52) U.S. Cl. 358/474

(57) ABSTRACT

An image display device according to the present invention is disclosed wherein a display function is added to an area sensor in which an optical sensor (constituted by a thin film light sensing diode) and a TFT are disposed in two dimensions on a transparent substrate to form a read function. Pixels each having a read function are each provided with a light transmitting area, and the thin film light sensing diodes and the TFTs are each formed using a substantially transparent material, so that the device itself is transparent. Therefore, a user can directly see the contents of a printed matter while the area sensor is placed on the printed matter. Further, an image can be read by, for example, designating the image required for the user from above the device. Consequently, it is possible to decrease the power consumption of the device.

### TECHNICAL FIELD

The present invention relates to an image display having an image pickup function. In particular, the present invention is concerned with a combined image pickup-display device which is capable of reading two-dimensional image information and performing data processing suitable for the purpose of use.

### BACKGROUND ART

As devices for reading two-dimensional information and displaying the read information by another method, there are widely known scanners, copying machines and facsimiles. In these devices, paper or a photograph is irradiated with a light source, and light reflected by or transmitted through the paper or photograph is passed through an optical system and read by an image sensor to acquire two-dimensional information of the paper or the photograph. Thereafter, the two-dimensional information thus acquired is subjected to various signal processing and is sent as digital information to a computer or a printer, whereby it can be displayed on a monitor or printed.

In the future, with development of networks and electrical information processing techniques, it will become possible to electrically process two-dimensional information of, for example, paper, printed matters and photographs in various forms. For example, with respect to read data subjected to processing for recognition, conversion, etc., if the functions such as search, translation, display of dictionary information, display of explanation, display of related information, or enlarged display, are used with the read data, it becomes possible to utilize read information in a more convenient and comfortable manner. In this case, an image reader requires the functions of: reading two-dimensional information, recognizing and processing acquired information, and displaying such information, which need to be integrated with one another. In addition, the image reader needs to have a reduced thickness and weight and provide convenience.

A conventional technique combining the said image reader with a display unit is disclosed, for example, in Japanese Patent Laid-Open Publication No. 2001-292276. Since this combined device is provided with both an area sensor and a display element on a main surface of the same substrate, displaying image information read by the area sensor makes it possible to check the contents thereof. According to this structure, however, a printed matter cannot be seen during reading image information, That is, it is not possible to display information at the same time of reading.

A conventional technique for solving this problem is disclosed, for example, in Japanese Patent Laid-Open Publication No. Hei 5 (1993)-89230. The device disclosed therein is of a structure wherein a liquid crystal display having a light receiving element and a surface emission element laminated to each other. To read an image from a printed matter, the printed matter is brought into close contact with the device and the surface emission element is allowed to emit light. The image thus read can be displayed using the liquid crystal display located on the side opposite to the reading surface.

According to the above conventional technique, however, when the device is moved, a time lag occurs in display, thus giving rise to the problem that it takes time until the contents of the printed matter can be viewed. Because of the same cause there also is the problem that an image becomes blurred due to hand movement when the device is used in an automobile. Further, in the aforesaid conventional technique, since a printed matter is read and displayed constantly, the power consumption is high and the device is not suitable for portable use.

### DISCLOSURE OF THE INVENTION

In the present invention, a display function comprising a light emission element and a thin film transistor (hereinafter referred to as “TFT”) is added to an area sensor wherein an optical sensor (constituted by a thin film light sensing diode) and a TFT are disposed in two dimensions on a transparent substrate to form a read function. By placing this area sensor having the display function on a printed matter, e.g., a book, two-dimensional image information is read. Pixels having a read function are each provided with a light transmitting area. Further, since the thin film light sensing diode and the TFT are each formed of a substantially transparent material, the device itself is transparent, thus allowing a user to see the contents of a printed matter directly while placing the area sensor on the printed matter. Therefore, even when the device is moved, the user can immediately see the contents of the printed matter. Besides, since the user reads an image only as necessary, for example, by designating a required image from above the apparatus, it is possible to solve the foregoing problems. Moreover, since the device is transparent, if an enlarged display of a character, a drawing or the like, or a display of dictionary information, translation, explanatory sentence, related information, or the like is used, not only an enlarged display but also such a display method as an information lens which enlarges information becomes possible in such a scene as that in which a conventional magnifying glass is used.

A concrete and basic construction of the present invention is as follows. A combined image pickup-display device according to the present invention comprises at least a light transmitting substrate, a plurality of pixels arranged on a first surface of the light transmitting substrate, and a display section, each of the pixels having at least a photoelectric conversion element portion and a light transmitting area, a scanning object being disposed on a second surface side of the light transmitting substrate. A light shielding film is formed in the photoelectric conversion element portion on the side opposite to the light transmitting substrate, light outputted from the second surface side of the light transmitting substrate being detected by the photoelectric conversion element portion, and the scanning object being visible from the first surface side even while the scanning object is read by the device.

The present invention can be applied to both a mode in which each display area in the display section is provided within each pixel and a mode in which each display area in the display section is provided in an area different from the pixels. In both modes, the device of the present invention is characterized by being optically see-through. In the mode wherein each display area is provided in each pixel, both display and image pickup element are formed in an integrated fashion, and thus this mode is superior in operability. On the other hand, in the mode wherein the display section is provided in an area different from the image pickup area having the pixels, the display area is separated and therefore this mode is advantageous to a high-definition display.

### BRIEF DESCRIPTION OF THE DRAWINGS

FIG. 1 is a perspective view of a combined image pickup-display device according to a first embodiment of the present invention;

FIG. 2 is a layout plan view of a pixel in the device of the first embodiment;

FIG. 3 is a conceptual diagram of an image to be read and pixels;

FIG. 4 is a conceptual diagram of pixels when the image to be read has been detected;

FIG. 5 is a perspective view showing an example of use of the combined image pickup-display device according to the present invention;

FIG. 6 is a sectional view of the combined image pickup-display device of the first embodiment;

FIG. 7 is a flow chart explaining the operation of the combined image pickup-display device of the first embodiment;

FIG. 8A is a sectional view showing a step in a manufacturing process according to the first embodiment;

FIG. 8B is a sectional view showing a further step in the manufacturing process according to the first embodiment;

FIG. 8C is a sectional view showing a still further step in the manufacturing process according to the first embodiment;

FIG. 8D is a sectional view showing a still further step in the manufacturing process according to the first embodiment;

FIG. 9 is a layout plan view of a pixel in a combined image pickup-display device according to a second embodiment of the present invention;

FIG. 10 is a sectional view of the combined image pickup-display device of the second embodiment;

FIG. 11A is a sectional view showing a step in a manufacturing process according to the second embodiment;

FIG. 11B is a sectional view showing a further step in the manufacturing process according to the second embodiment;

FIG. 11C is a sectional view showing a still further step in the manufacturing process according to the second embodiment;

FIG. 12 is a sectional view of a combined image pickup-display device according to a third embodiment of the present invention;

FIG. 13 is a flow chart explaining the operation of the combined image pickup-display device of the third embodiment;

FIG. 14A is a sectional view showing a step in a manufacturing process according to the third embodiment;

FIG. 14B is a sectional view showing a further step in the manufacturing process according to the third embodiment;

FIG. 14C is a sectional view showing a still further step in the manufacturing process according to the third embodiment;

FIG. 14D is a sectional view showing a still further step in the manufacturing process according to the third embodiment;

FIG. 15 is a perspective view of a combined image pickup-display device according to a fourth embodiment of the present invention;

FIG. 16 is a layout plan view of a pixel in the device of the fourth embodiment;

FIG. 17 is a sectional view of the combined image pickup-display device of the fourth embodiment;

FIG. 18A is a sectional view showing a step in a manufacturing process according to the fourth embodiment;

FIG. 18B is a sectional view showing a further step in the manufacturing process according to the fourth embodiment;

FIG. 18C is a sectional view showing a still further step in the manufacturing process according to the fourth embodiment;

FIG. 19 is a sectional view of a combined image pickup-display device according to a fifth embodiment of the present invention; and

FIG. 20 is a diagram showing a schematic structure of a combined image pickup-display device according to a sixth embodiment of the present invention.

### BEST MODE FOR CARRYING OUT THE INVENTION

### First Embodiment

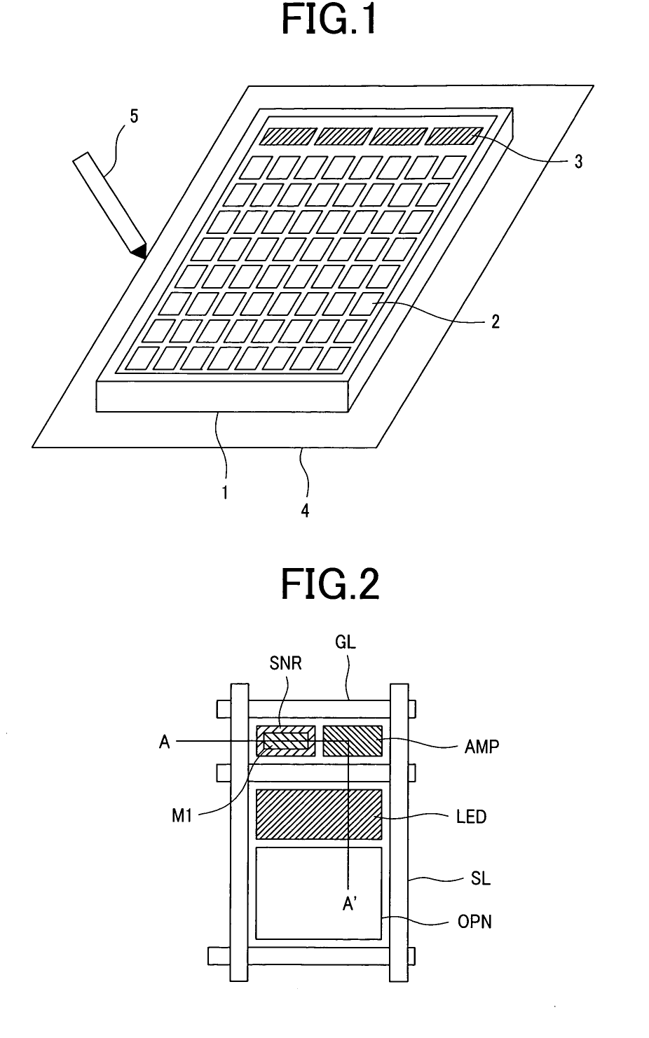

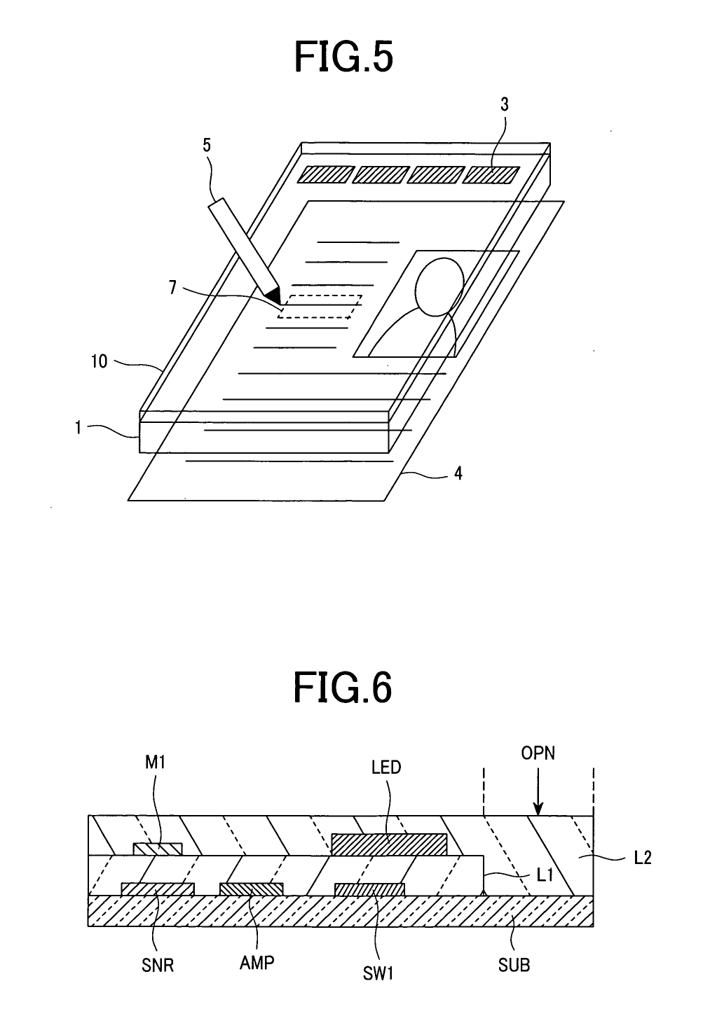

A combined image pickup-display device according to a first embodiment of the present invention will be described with reference to FIGS. 1 to 4. FIG. 1 is a schematic perspective view of the combined image pickup-display device of the first embodiment. Pixels 2 having both an image pickup function and a display function are arranged planarly on a transparent substrate 1 having a diagonal length of about 20 cm and a thickness of about 2 mm. Although sixty four pixels 2 are schematically shown in FIG. 1, actually a larger number of pixels are arranged at pitches of about 40 μm. A member associated with setting of a position using a touch pen is not shown in FIG. 1 (only touch pen is shown) since it would make the drawing complicated. The position setting portion using the touch pen is shown in FIG. 5. As to the setting of a position using the touch pen, the same construction is adopted in other embodiments. FIG. 2 is a plan view showing the construction of a pixel 2. In each of the areas surrounded with plural gate lines GL and plural signal lines SL that cross the gate lines in a matrix form, there are provided a thin film light sensing diode (optical sensor) SNR, a light shielding film M1, a signal conversion and amplifying circuit AMP, a light emitting diode LED, and a light transmitting area OPN. Usually, the thin film light sensing diode (optical sensor) SNR is formed by a polycrystalline silicon film, and an aluminum (Al) film is used for the light shielding film M1. The signal conversion and amplifying circuit AMP is constituted using a polycrystalline silicon TFT. In this embodiment, moreover, an organic light emitting diode is used as the light emitting diode LED.

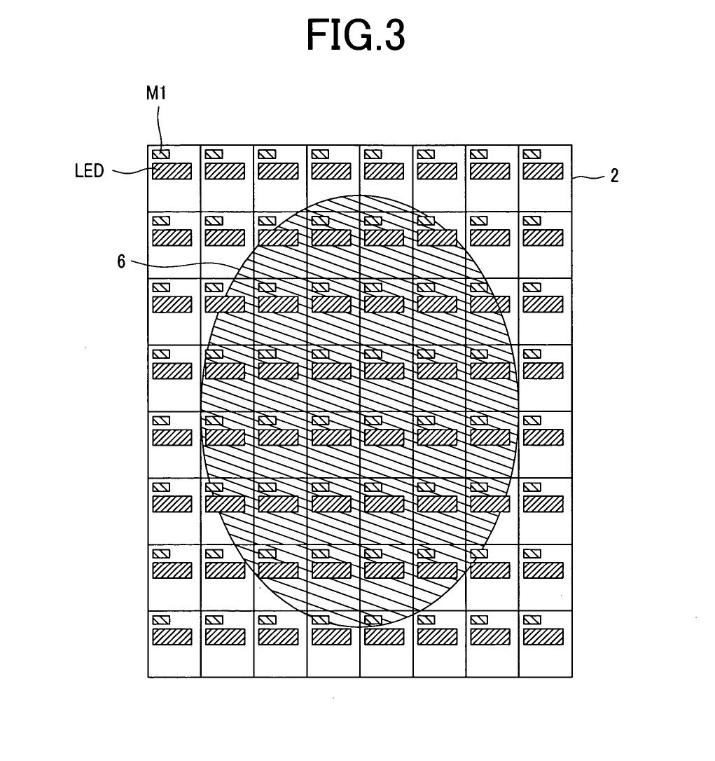

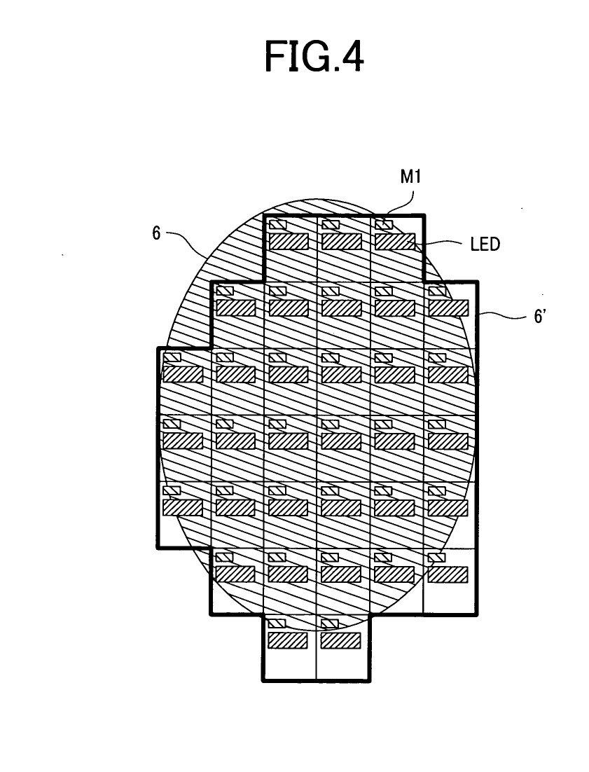

FIG. 3 shows the state where an elliptic pattern is read using this device. Within each of the sixty four pixels 2 shown schematically, as noted above, there are arranged the optical sensor, light shielding film M1, amplifier circuit AMP, and light emitting diode LED. Since the polycrystalline silicon film and wiring which constitute the optical sensor and the amplifier circuit are substantially transparent, a printed matter can be seen through the area exclusive of the light shielding film M1 and the light emitting diode LED. In reading an image, the image is recognized at the portion where the elliptic pattern, indicated by reference numeral 6, and the light shielding film M1 overlap each other. Therefore, pixels which actually recognize the elliptic pattern 6 are those in an area 6′ (the area surrounded with a thick line) shown in FIG. 4.

FIG. 5 is a perspective view explaining an outline of a method of reading an image with use of a touch pen. A transparent substrate 1 with pixels 2 arranged thereon is provided, which is the same as that illustrated in FIGS. 1 and 2. The transparent substrate 1 is disposed on top of a printed matter 4 to be read.

A touch panel 10 is disposed on a surface of the transparent substrate 1. The touch panel 10 has an upper transparent electrode floated by a spacer and a lower transparent electrode. A change in resistance value of a point of contact under pressing of the touch pen is measured, whereby the position of the touch pen position can be detected. The thus-detected positional information is subjected to electric signal processing by an integrated circuit 3 to actuate a pixel sensor. In this way, image information is read using the touch pen. As to basic construction and operation for the setting of position using the touch panel and the touch pen and for the reading of image based thereon, it suffices to use conventional ones. Therefore, the details thereof are here omitted.

In this embodiment, as shown in FIG. 5, by specifying an area 7 for reading an image with use of the touch pen indicated by reference numeral 5, it is possible to read only the required image. A concrete read operation will be described later. In this embodiment, an image is read only when required, that is, it is not necessary to read an image constantly, and therefore it is possible to decrease the power consumption.

A sectional structure of the combined image pickup-display device will now be described with reference to FIG. 6. FIG. 6 is a sectional view taken along line A-A′ of the image shown in FIG. 2. FIG. 6 shows summarily an example of space layout of the thin film light sensing diode SNR, the signal conversion and amplifying circuit AMP formed by polycrystalline silicon TFT, the polycrystalline silicon TFT circuit SW1, the light shielding film M1, and the organic light emitting diode LED. FIGS. 10, 12, 17 and 19 are also such general sectional view as FIG. 6. The details of the laminate are illustrated in another drawing.

A thin film photodiode SNR of a polycrystalline silicon film, a signal conversion and amplifying circuit AMP of polycrystalline TFT, and a polycrystalline silicon TFT circuit SW1 for driving an organic light emitting diode are formed on a transparent substrate SUB. Then, an interlayer insulating film L1 is formed on the transparent substrate SUB, the thin film photodiode SNR, the signal conversion and amplifying circuit AMP, and the polycrystalline silicon TFT circuit SW1. A light shielding film M1 and an organic light emitting diode LED are disposed on the interlayer insulating film L1. These members are covered with a protective film L2 as a second insulating film. Each pixel is formed in this way. In the light transmitting area OPN of each pixel, the interlayer insulating film L1 is removed.

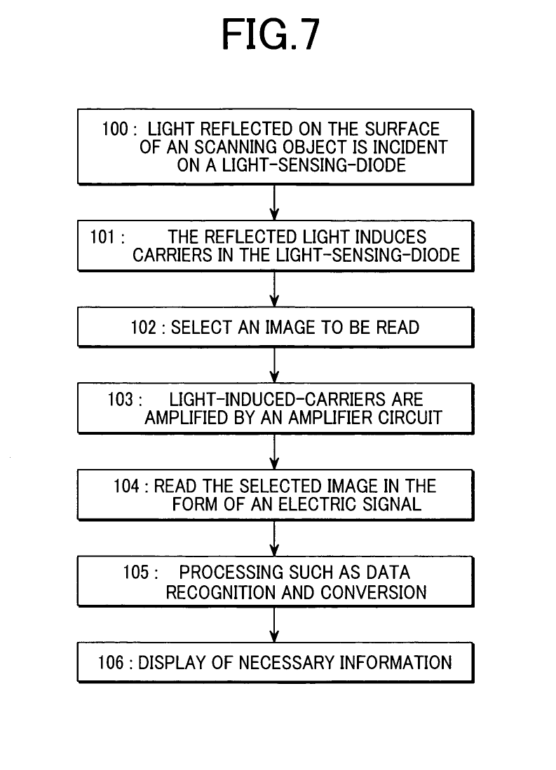

Next, the operation of the combined image pickup-display device will be described. First, the substrate SUB is brought into close contact with a printed matter 4. Extraneous light is incident on the device from the protective film L2 side. This incident light is reflected on the surface of the printed matter and thereafter reaches the photodiode SNR (step 100 in FIG. 7). The light shielding film M1 shields light which is incident on the light sensing diode SNR directly from the protective film L2 side. Therefore, light carriers are produced within the light sensing diode SNR in accordance with whether the reflected light from the printed matter is strong or weak (step 101 in FIG. 7). Next, voltage is applied to the gate line GL and signal line SL of a pixel to select a pixel for reading an image (step 102 in FIG. 7). In the selected pixel, the light carriers produced in the light sensing diode SNR are amplified by the amplifier circuit AMP (step 103 in FIG. 7).

By repeating the same operation for each of adjacent pixels, two-dimensional information of the selected image can be read in the form an electric signal (step 104 in FIG. 7). To drive the pixels arranged in a matrix shape, the conventional matrix driving method can be used. Therefore, the details thereof are here omitted. This is also true of the embodiments which follow.

Next, such processing as data recognition and conversion are performed by the integrated circuit 3 (step 105 in FIG. 7) as required. When making a display, the amount of light emitted is changed for each pixel by changing the voltage to be applied to the organic light emitting diode LED with use of the polycrystalline silicon TFT circuit SW1, thereby performing search, translation, display of dictionary information, display of explanation, display of related information, or enlarged display in arbitrary places (step 106 in FIG. 7).

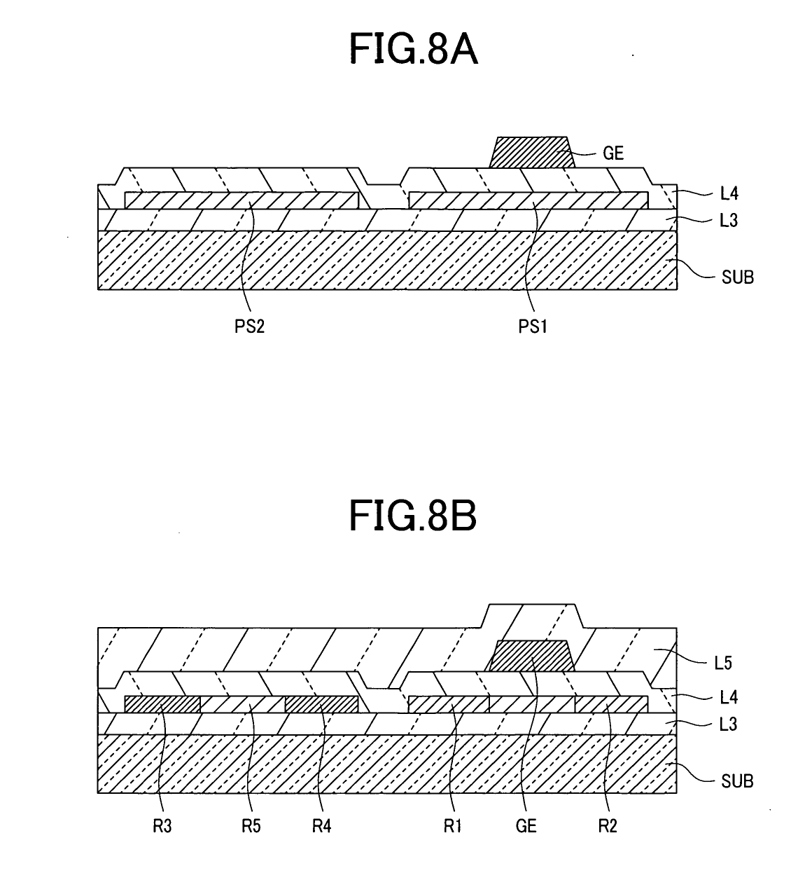

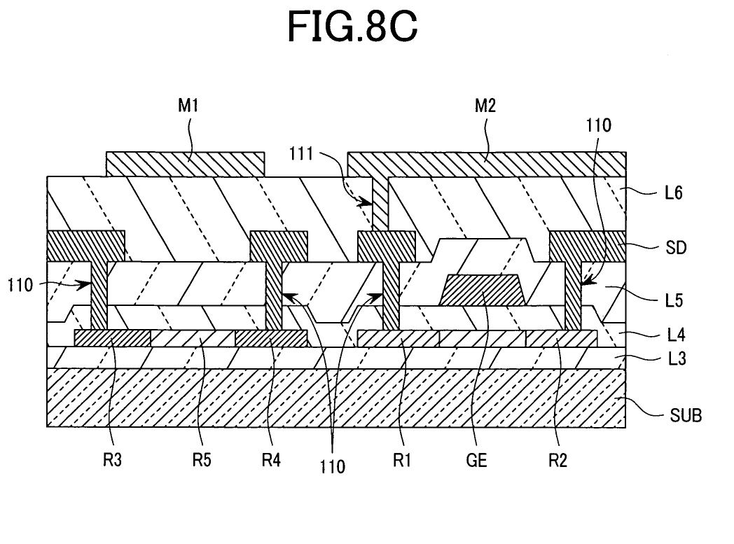

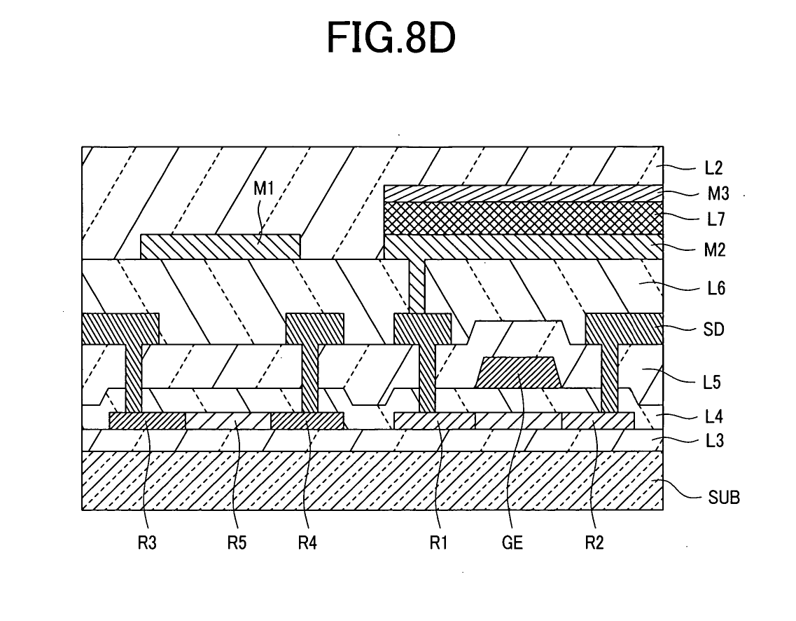

Next, a method of manufacturing this combined image pickup-display device will be described with reference to FIGS. 8A to 8D. First, a buffer layer L3 of a silicon oxide film is deposited on a transparent glass substrate SUB. Then, a polycrystalline silicon film PS is formed. Specifically, in this step, an amorphous silicon film is deposited by plasma CVD (Chemical Vapor Deposition) and is then crystallized by a laser annealing crystallization method using an excimer laser. In this embodiment, a polycrystalline silicon film PS having a field effect mobility of about 200 cm²/Vs is formed. Further, the polycrystalline silicon film PS is processed into desired island shapes PS1 and PS2. Then, a silicon oxide film is deposited by plasma CVD so as to cover the island-shaped polycrystalline silicon films PS1 and PS2 to form a gate insulating film L4. Next, ITO (Indium Thin Oxide) is deposited by sputtering and a transparent gate electrode film GE of a desired shape is formed (FIG. 8A).

Next, in the island-shaped polycrystalline silicon films PS1 and PS2, impurity ions are introduced into regions serving as source R1 and drain R2 of TFT and as cathode layer R3 and anode layer R4 of the light sensing diode. Then, an interlayer insulating film L5 which is a silicon oxide film is deposited on top of the substrate thus provided. The setting of impurity regions in the semiconductor layer can be done by a conventional method such as, for example, a method wherein ion implantation is performed with the gate electrode region itself as a mask region or a method wherein ion implantation is performed locally to a limited desired region.

Thereafter, a furnace annealing method is performed for activating the introduced impurity to form a source diffusion layer R1 and a drain diffusion layer R2 of TFT and a cathode layer R3 and an anode layer R4 of the light sensing diode. At this time, an intrinsic region R5 without impurity ions introduced therein is left in order to improve the light receiving efficiency of the light sensing diode (FIG. 8B). Although only an n-type channel TFT is shown as a basic example, a p-type channel TFT or a TFT of an LDD (Lightly Doped Drain) structure is formed based on an actual circuit configuration.

Next, desired contact holes 110 are formed in the insulating films L4 and L5, followed by deposition of ITO by sputtering. Subsequently, transparent source-drain electrodes SD are formed by the conventional etching process. Thereafter, an interlayer insulating film L6 which is a silicon nitride film is deposited and hydrogenation is performed by plasma processing.

Further, contact holes 111 are formed in the interlayer insulating film L6, followed by deposition of Al. Then, by the conventional etching process, a lower electrode M2 of the organic light emitting diode is formed and at the same time a light shielding film M1 is formed (FIG. 8C). Though not shown here, the interlayer insulating films L5 and L6 in the light transmitting region are removed simultaneously with the formation of contact holes.

An organic light emitting material L7 is laminated by the conventional vapor deposition method and thereafter a transparent electrode serving as an upper electrode M3 is formed to form a light emitting element (FIG. 8D). Next, a transparent protective insulating film L2 of a low dielectric constant is deposited using an organic material to complete a transparent area sensor.

In this embodiment, the lower electrode M2 of the organic light emitting diode and the light shielding film M1 are formed by electrodes in the same layer, whereby the gate electrode GE and the source-drain electrodes SD can be transparent. Therefore, the thin film light sensing diode and the polycrystalline silicon TFT circuit can be made substantially transparent. Further, removing the interlayer insulating film L1 in the light transmitting region makes it possible to improve the transmittance of light. Also, with respect to the gate lines GL and signal lines SL, it is possible to improve the transmittance by forming them with use of a transparent electrode such as ITO. As a result of improvement of the transmittance, not only does it become easier for a user to see a printed matter, but also the light incident on the light sensing diode can be strengthened and the S/N ratio is improved. As a result, the read speed is improved. For example, if the gate electrode of a thin film transistor is made transparent to transmit light, an off-leakage current increases upon radiation of light. However, the signal deterioration caused by the leakage can be prevented by forming a holding capacitance for the member concerned for example. This region can also be made transparent by implementing the function of the integrated circuit 3 with use of a polycrystalline silicon TFT circuit.

### Second Embodiment

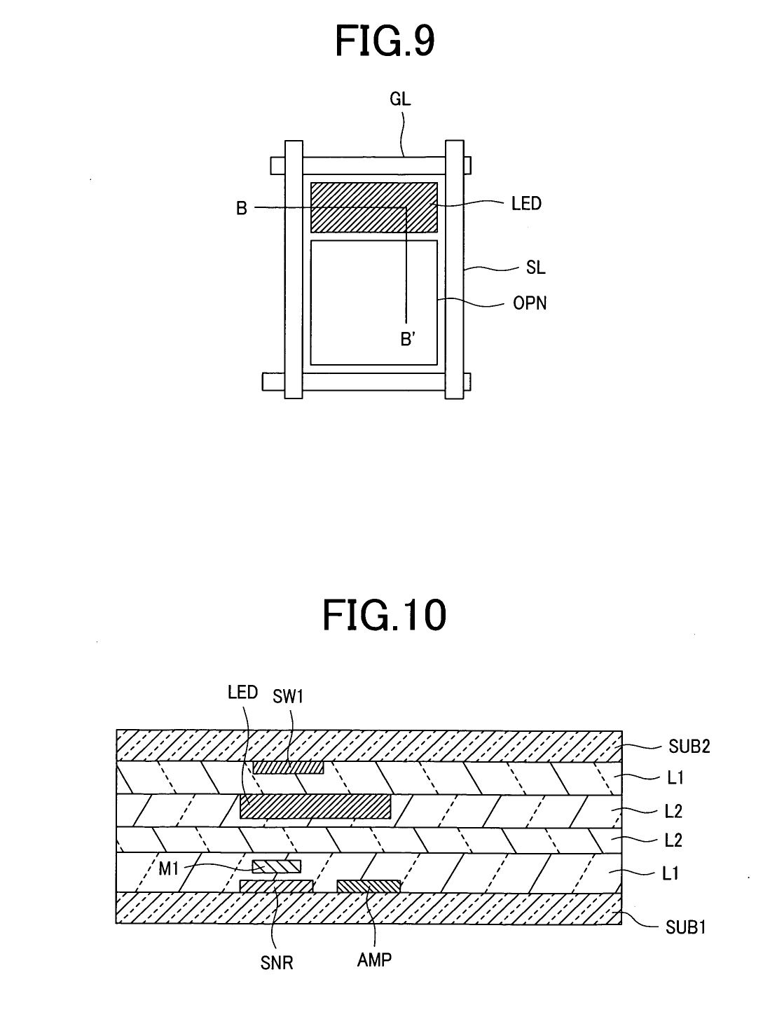

A schematic structure of a combined image pickup-display device according to a second embodiment of the present invention is the same as that shown in FIG. 1. FIG. 9 is a plan view of a pixel 2 used in this embodiment. FIG. 10 is a sectional view taken on line B-B′ of the pixel 2 in FIG. 9.

The device of this embodiment has a laminated structure of both a transparent substrate SUB1 having an image pickup function and a transparent substrate SUB2 having a display function. A thin film light sensing diode SNR of a polycrystalline silicon film and a signal conversion and amplifying circuit AMP of a polycrystalline silicon TFT are formed on the transparent substrate SUB1. A light shielding film M1 is formed on the thin film light sensing diode SNR through an interlayer insulating film L1. Further, a protective insulating film L2 is formed on the top. On the other hand, a polycrystalline silicon TFT circuit SW1 for driving an organic light emitting diode is formed on the transparent substrate SUB2, and an organic light emitting diode LED is formed above the TFT circuit SW1 through an interlayer insulating film L1. A protective insulating film L2 is formed so as to cover the organic light emitting diode LED. Both substrates SUB1 and SUB2 are laminated below and above protective insulating films L2, respectively.

In this embodiment, the thin film light sensing diode SNR and the light shielding film M1, as well as the organic light emitting diode LED, are superimposed one on another vertically. As in the first embodiment, reflected light of extraneous light incident from the protective film L2 side is detected by the optical sensor SNR and image information of a printed matter can be read in the form of an electric signal.

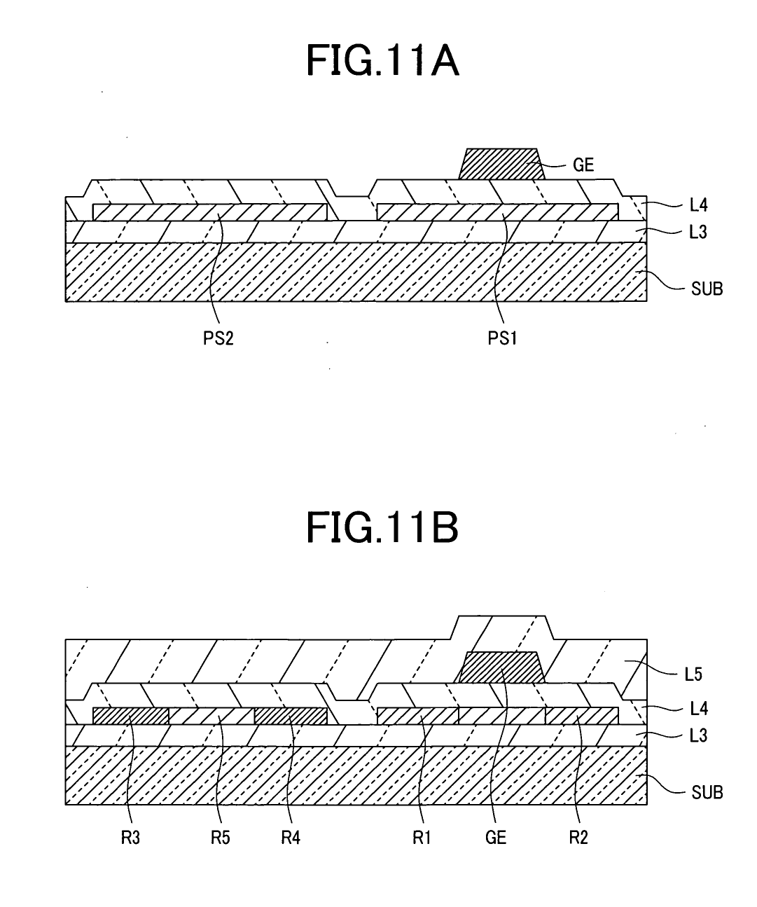

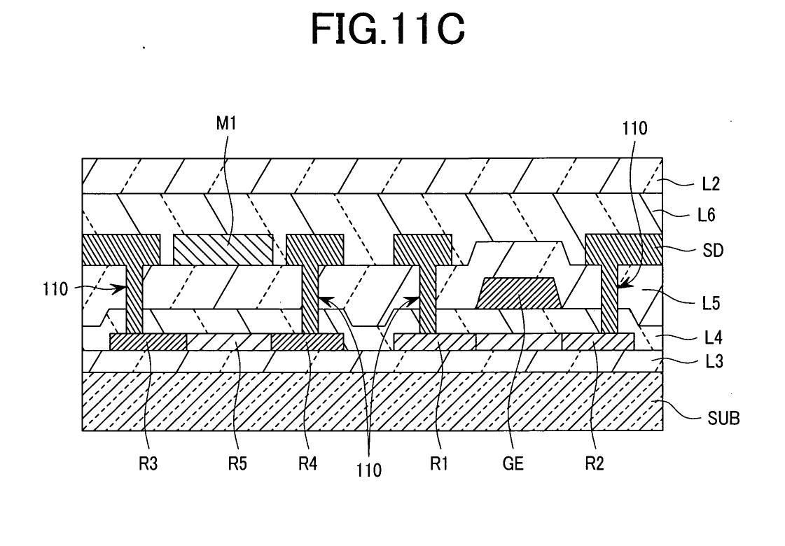

Next, a method of fabricating a transparent substrate having an image pickup function will be described with reference to FIGS. 11A to 11C. First, a buffer layer L3 of a silicon oxide film is deposited on a transparent glass substrate SUB. An amorphous silicon film-is deposited on the buffer layer L3 by plasma CVD and is then crystallized by a laser annealing crystallization method using an excimer laser. In this way, a polycrystalline silicon film PS having a field effect mobility of about 200 cm²/Vs is formed. The polycrystalline silicon film PS is processed into desired island shapes (PS1, PS2) and thereafter a silicon oxide film is deposited by plasma CVD so as to cover the island-shaped polycrystalline silicon films PS1 and PS2, thereby forming a gate insulating film L4.

Next, a gate electrode film consisting mainly of Mo is deposited by sputtering, and a gate electrode GE of a desired shape is formed by a conventional etching process (FIG. 11A).

Then, in the island-shaped polycrystalline silicon films PS1 and PS2, impurity ions are introduced by ion implantation into regions serving as source R1 and drain R2 of TFT and cathode layer R3 and anode layer R4 of a light sensing diode. An interlayer insulating film L5, which is a silicon oxide film, is deposited on the substrate thus provided. Then, furnace annealing method for activation is performed to form a source diffusion layer R1 and a drain diffusion layer R2 of TFT, as well as a cathode layer R3 and an anode layer R4 of the light sensing diode. At this time, an intrinsic region R5 with impurity ions not introduced therein is allowed to remain in order to enhance the light receiving efficiency of the light sensing diode (FIG. 11B).

Although an n-type channel TFT is shown here, there is formed a p-type channel TFT or a TFT of LDD structure when required in an actual circuit configuration.

Next, contact holes 110 are formed in the gate insulating film L4 and the interlayer insulating film L5, followed by deposition of a laminate film of Al and TiN by sputtering. Then, the laminate film is processed into a desired shape by the conventional etching process, forming source-drain electrodes SD and a light shielding film M1. Thereafter, an interlayer insulating film L6, which is a silicon nitride film, is deposited and hydrogenation is performed by plasma processing. Subsequently, a transparent protective insulating film L2 of a low dielectric constant is deposited using an organic material (FIG. 11C).

According to this second embodiment, the optical sensor SNR and the light shielding film M1, as well as the organic light emitting diode LED, are superimposed one on another vertically, whereby the area of the light transmitting area OPN can be made large and the transmittance is improved. Further, since the source-drain electrode SD and the light shielding film M1 are formed in the same layer, there is no possibility that the spacing between the source-drain electrode and the light shielding film may be shortened or both electrodes may overlap each other due to a mask alignment error. Consequently, an increase of parasitic capacitance based on such phenomenon can be suppressed.

### Third Embodiment

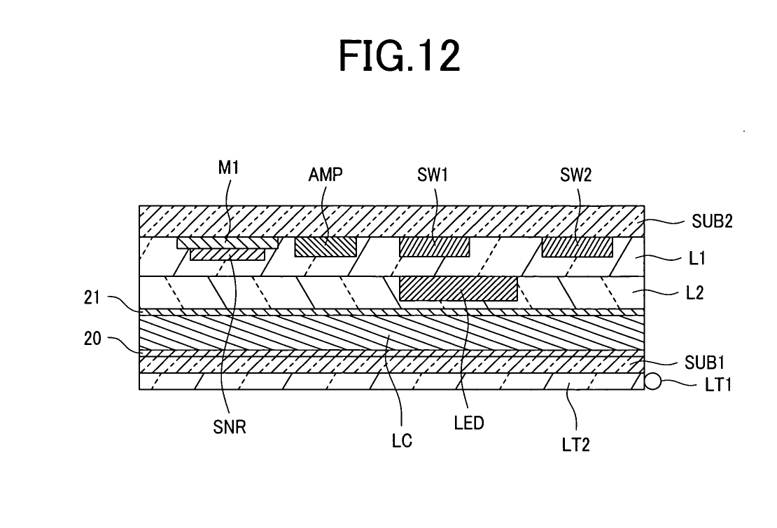

An image pickup-display device according to a third embodiment of the present invention uses a liquid crystal layer. A schematic structure of the device of this third embodiment is the same as that shown in FIG. 1. A plan view of a pixel 2 is the same as FIG. 2. FIG. 12 is a sectional view taken on line A-A′ of the pixel 2.

A liquid crystal layer LC is sandwiched between a first transparent substrate SUB1 carrying a light source thereon and a second transparent substrate SUB2 carrying thereon a thin film light sensing diode SNR, an organic light emitting diode LED and a desired integrated circuit.

A light conducting plate LT2 is formed on the transparent substrate SUB1 and a light source LT1 is disposed on at least one end side of the waveguide plate. On the other hand, an electrode 20 for driving the liquid crystal is formed on a second surface of the transparent substrate SUB1, which is the side opposite to the transparent substrate SUB1. The thin film light sensing diode SNR is mounted on the transparent substrate SUB2 through a light shielding film M1. Further, a signal conversion and amplifying circuit AMP, a polycrystalline silicon TFT circuit SW1 for driving the organic light emitting diode, and a TFT circuit SW2 for driving the liquid crystal layer LC are mounted on the transparent substrate SUB2. An interlayer insulating film L1 is formed so as to cover these components. The organic light emitting diode LED is formed on the interlayer insulating film L1 and a protective insulating film L2 is formed thereon. Further, an electrode 21 for driving the liquid crystal is formed on the protective insulating film L2. The thin film light sensing diode SNR, the signal conversion and amplifying circuit AMP, and the TFT circuit SW2 for driving the liquid crystal layer LC are each formed by a polycrystalline silicon film. As to the light conducting plate LT2 and the light source LT1, it suffices to produce them using the front light technique which is adopted in the field of liquid crystal display.

As noted above, since the liquid crystal layer LC is sandwiched between two transparent substrates SUB, light passes therethrough when voltage is not applied to the liquid crystal by the polycrystalline silicon TFT circuit SW2.

Moreover, as described earlier, the light source LT1 for lighting a printed matter and displaying an image, as well as the light conducting plate LT2, are provided in the lowest layer.

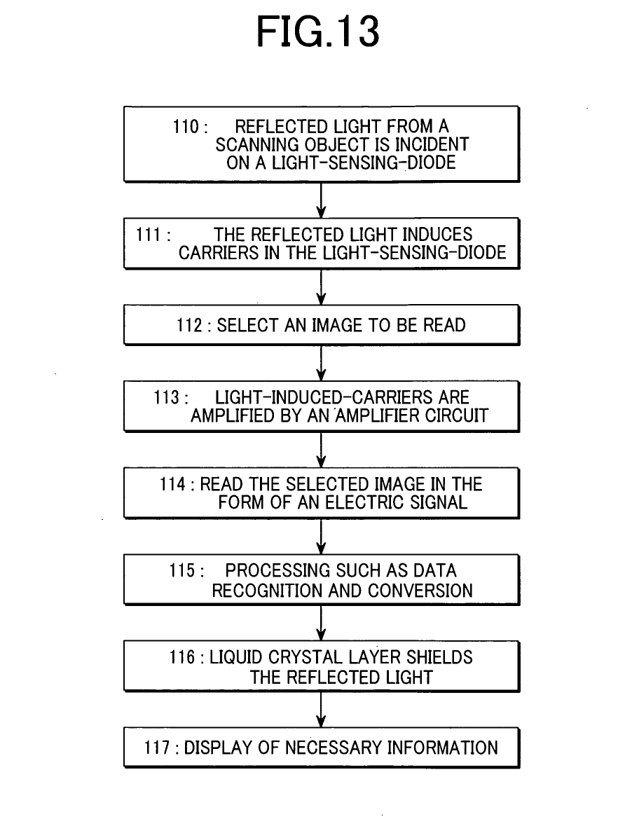

Next, the operation of this combined image pickup-display device will be described with reference to FIGS. 12 and 13. First, the light conducting plate LT2 is brought into close contact with a printed matter and the light source LT1 is turned ON so as to illuminate the printed matter. The light conducting plate LT2 causes the light emitted from the light source to be scattered to the printed matter side and at the same time causes reflected light from the printed matter to pass therethrough, allowing the reflected light to reach the light sensing diode SNR (step 110 in FIG. 13). Since the light shielding film M1 shields extraneous light incident on the light sensing diode from the substrate side, light carriers are produced within the light sensing diode SNR in accordance with whether the reflected light from the printed matter is strong or weak (step 111 in FIG. 13) Next, a pixel for reading an image is selected by applying voltage to both gate line GL and signal line SL (step 112 in FIG. 13). In the selected pixel, light-induced carriers produced in the light sensing diode are amplified by the amplifier circuit AMP (step 113 in FIG. 13). By repeating the same operation for adjacent pixels, it is possible to read two-dimensional information of the selected image in the form of an electric signal (step 114 in FIG. 13). Next, processing such as data recognition and conversion are performed by the integrated circuit 3 (step 115 in FIG. 13) as required.

When making a display, voltage is applied to the liquid crystal layer through electrodes 20 and 21 by the polycrystalline silicon TFT circuit SW2 to shield reflected light from the printed matter (step 116 in step 13). Thereafter, the amount of light to be emitted is changed by changing the voltage which is applied to the organic light emitting diode by the polycrystalline silicon TFT circuit SW1 to make search, translation, display of dictionary information, display of explanation, display of related information, or enlarged display, in arbitrary places (step 117 in FIG. 13).

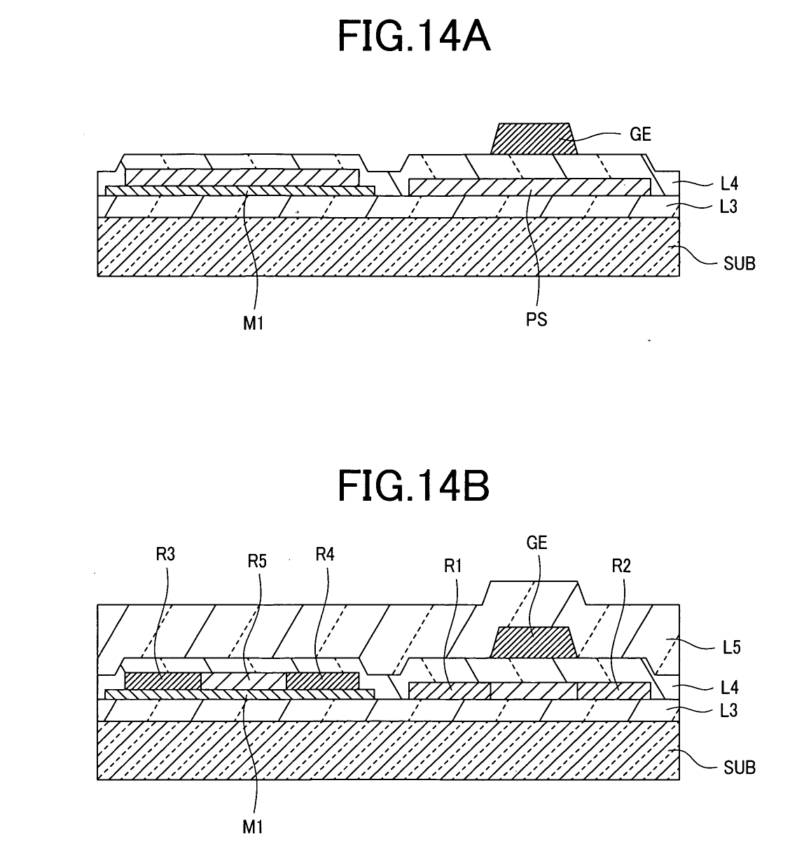

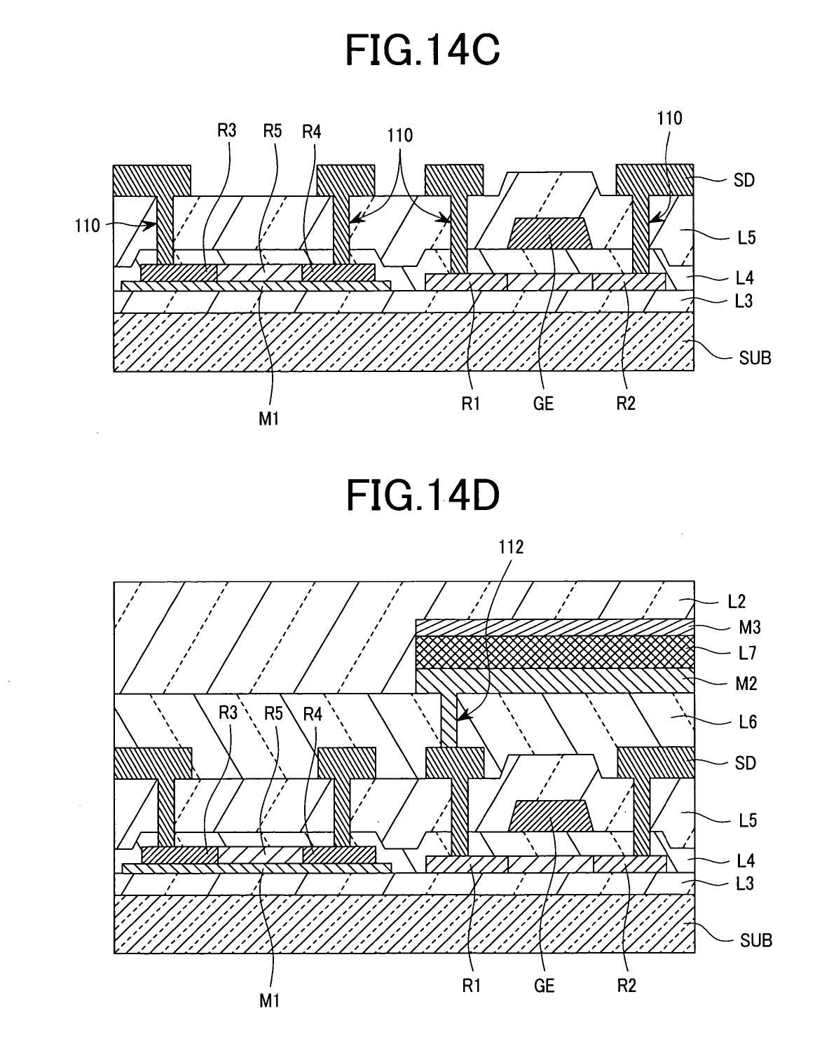

Next, a method of manufacturing this image pickup-display device will be described with reference to FIGS. 14A to 14D. First, a buffer layer L3 of a silicon oxide film is formed on a transparent glass substrate SUB and a light shielding film M1 is formed in a desired shape on the buffer layer L3. An amorphous silicon layer is deposited on the thus-provided substrate by plasma CVD and is then crystallized by a laser annealing crystallization method using an excimer laser to form a polycrystalline silicon film PS having a field effect mobility of about 200 cm²/Vs. The polycrystalline silicon film PS is then processed into desired island shapes PS3 and PS4. Then, a silicon oxide film is deposited by plasma CVD so as to cover the polycrystalline silicon films PS3 and PS4, thereby forming a gate insulating film L4. Next, ITO is deposited by sputtering and a transparent gate electrode film GE is formed by the conventional etching process (FIG. 14A).

Then, impurity ions are introduced into the polycrystalline silicon films PS1 and PS2 by ion implantation and an interlayer insulating film which is a silicon oxide film is deposited thereon. Then, furnace annealing method is performed for activation of the impurity thus introduced and there are formed a source diffusion layer R1 and a drain diffusion layer R2 of TFT, as well as a cathode layer R3 and an anode layer R4 of an optical sensing diode. At this time, an intrinsic region R5 with impurity ions not introduced therein is allowed to remain in order to enhance the light receiving efficiency of the light sensing diode (FIG. 14B). Although only an n-type channel TFT is shown, actually a p-type channel TFT and a TFT of LDD structure are also formed as required in the circuit used.

Next, contact holes 110 are formed in the gate insulating film L4 and the interlayer insulating film L5 and thereafter an ITO film is deposited by sputtering. The ITO film is then processed into a desired shaped by the conventional etching process to form a transparent source-drain electrode SD (FIG. 14C). Thereafter, a silicon nitride film L6 is deposited on the source-drain electrode SD and hydrogenation is performed by plasma processing. Contact holes 112 are formed in the silicon nitride film L6, followed by deposition of an ITO film. The ITO film is then processed into a desired shape to form a lower electrode M2 of an organic light emitting diode. Further, an organic light emitting material L7 and an Al electrode as an upper electrode M3 are laminated onto the lower electrode M2 of the organic light emitting diode by vapor deposition. In this way there is formed a light emitting element (FIG. 14D).

Next, a transparent protective insulating film L2 of a low dielectric constant is deposited using an organic material. Thereafter, liquid crystal is sealed between the foregoing two substrates to complete a transparent area sensor by a method usually adopted in the field of liquid crystal.

According to this third embodiment, since a back light is used as the light source, it is possible to strengthen the light incident on the light sensing diode and the S/N ratio is improved. As a result, the read speed is improved. When making a display, reflected light from the printed matter is shield by the liquid crystal layer and therefore the display contrast is improved.

### Fourth Embodiment

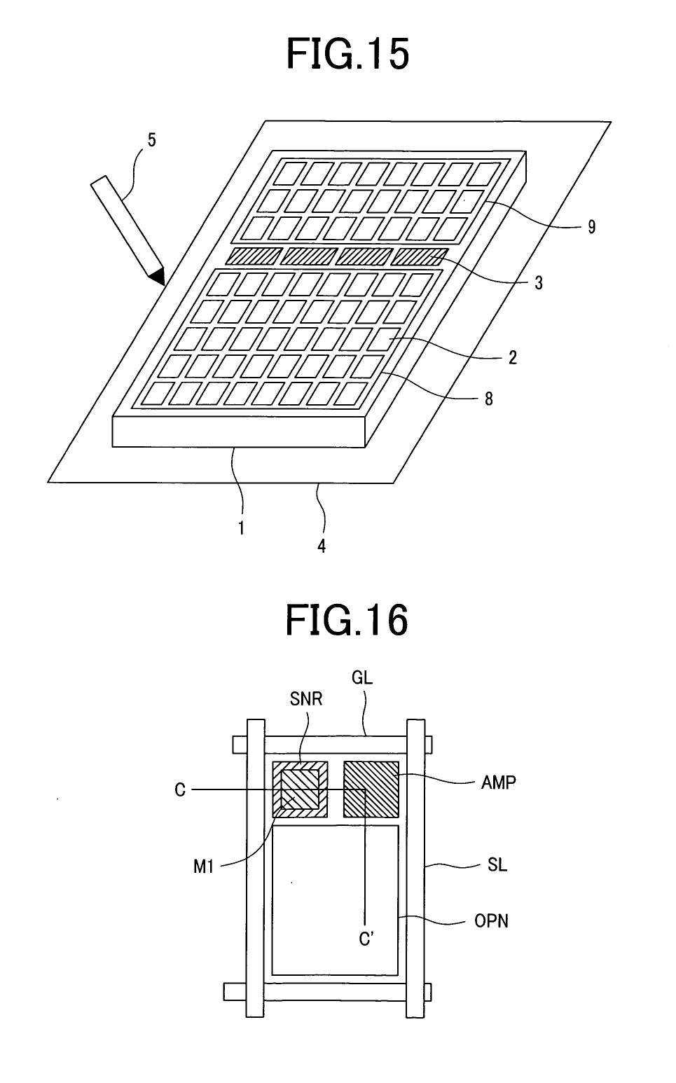

A combined image pickup-display device according to a fourth embodiment of the present invention is of a structure wherein a display region is separated. FIG. 15 is a perspective view showing a schematic structure of the device of this fourth embodiment. An image pickup device 8 and a display device 9, as well as an integrated circuit 3 for performing a signal processing, are formed on a transparent substrate 1 having a diagonal length of about 20 cm and a thickness of about 2 mm. As the display device 9 may be used, for example, a liquid crystal display device or an image display device using an organic light emitting diode. The display device 9 is not required to be transparent. FIG. 16 is a plan view of a pixel 2 used in the image pickup device. A thin film light sensing diode SNR of a polycrystalline silicon film, a light shielding film M1, a signal conversion and amplifying circuit AMP of a polycrystalline silicon TFT and a light transmitting area OPN are formed in an area surrounded by plural gate lines GL and plural signal lines SL which cross the gate liens GL in a matrix shape.

Next, a sectional structure of this combined image pickup-display device will be described with reference to FIG. 17. FIG. 17 is a sectional view taken on line C-C′ in FIG. 16. The thin film light sensing diode SNR of a polycrystalline silicon film and the signal conversion and amplifying circuit AMP of a polycrystalline silicon TFT are disposed on a transparent substrate SUB. The light shielding film M1 is provided in a desired region through an interlayer insulating film L1. A protective insulating film L2 is formed on the substrate thus provided. The interlayer insulating film L1 in the light transmitting area OPN is removed in order to improve the light transmissivity of the light transmitting area OPN.

As in the first embodiment, reflected light of extraneous light incident from the protective insulating film L2 side is detected by the light sensing diode SNR and the amplifier circuit AMP, and image information of a printed matter can be read in the form of an electric signal.

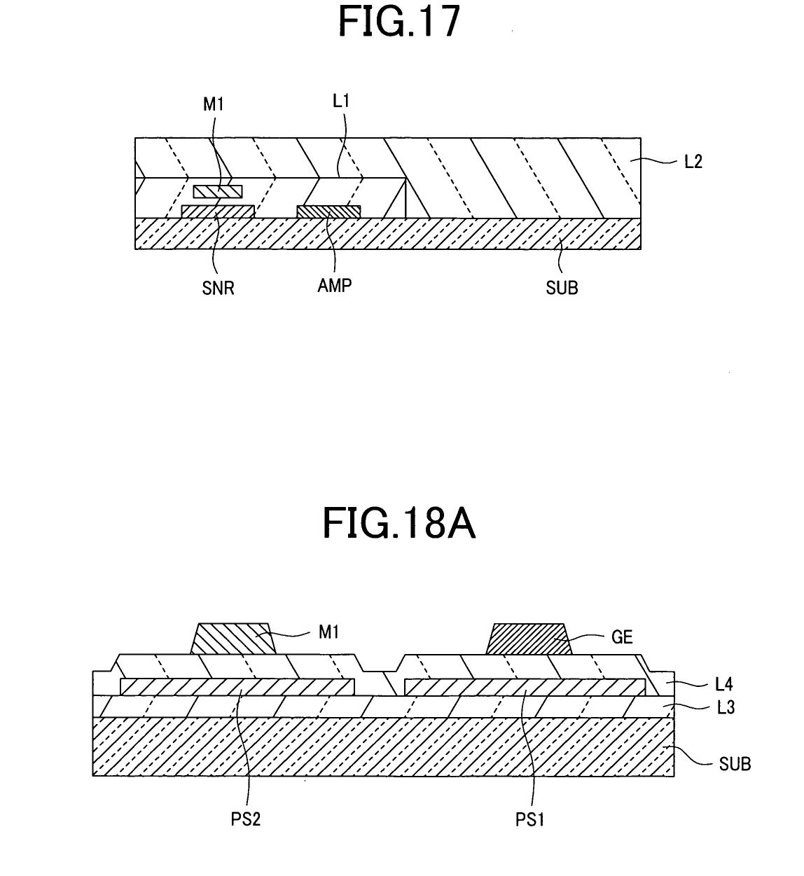

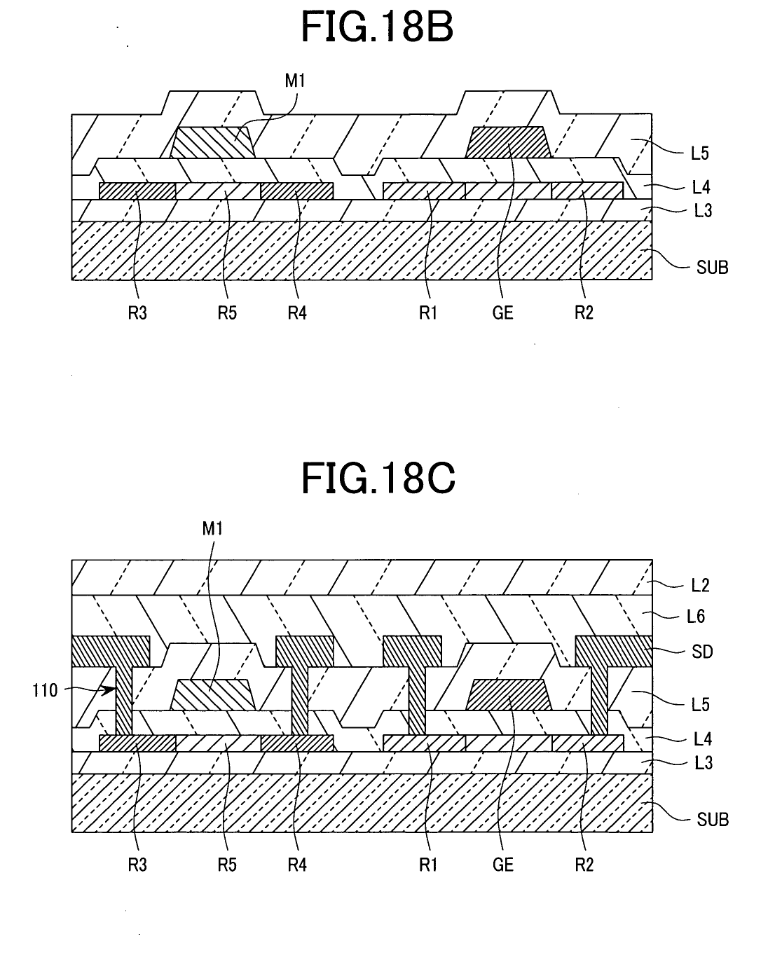

Next, a method of manufacturing this image pickup device will be described with reference to FIGS. 18A to 18C. First, a buffer layer L3 of a silicon oxide film is deposited on a transparent glass substrate SUS, then an amorphous film is deposited thereon by plasma CVD and is then crystallized by a laser annealing crystallization method using an excimer laser. In this way, a polycrystalline silicon film PS having a field effect mobility of about 200 cm²/Vs is formed. The polycrystalline silicon film PS is processed into desired island shapes PS1 and PS2 and thereafter a silicon oxide film L4 is deposited by plasma CVD so as to cover the island films PS1 and PS2. Then, the silicon oxide film is processed into a desired shape to form a gate insulating film L4. Next, a gate electrode film containing Mo as a main component is deposited by sputtering and a gate electrode GE and a light shielding film M1 are formed by the conventional etching process (FIG. 18A).

Then, impurity ions are introduced into the polycrystalline silicon films PS1 and PS2 by ion implantation. Further, an interlayer insulating film L5 which is a silicon oxide film is deposited so as to cover the gate electrode GE and the light shielding film M1. Subsequently, furnace annealing method is performed for activation of the introduced impurity and there are formed a source diffusion layer R1 and a drain diffusion layer R2 of TFT and a cathode layer R3 and an anode layer R4 of a light sensing diode. At this time, an intrinsic region R5 free of impurity ions is allowed to remain (FIG. 18B). Here, although only an n-type channel TFT is shown, actually a p-type channel TFT or a TFT of LDD structure is formed as required in a circuit configuration.

Next, contact holes 110 are formed in the gate insulating film L4 and the interlayer insulating film L5 and thereafter an ITO film is deposited by sputtering. The ITO film is then processed into a desired shape by etching to form a transparent source-drain electrode SD. Subsequently, an interlayer insulating film L6 which is a silicon nitride film is deposited on the substrate thus provided and hydrogenation is performed by plasma processing (FIG. 18C). Though not shown, the inerlayer insulating films L5 and L6 in the light transmitting area are removed simultaneously with formation of the contact holes in order to improve the light transmissivity of the light transmitting area. Thereafter, a transparent protective insulating film L2 of a low dielectric constant is deposited using an organic material.

According to the construction of this fourth embodiment, since the image pickup area and the display area are separated from each other, it is not necessary to provide a light emitting element within each pixel in the image pickup area. Consequently, the area of the light transmitting area OPN can be enlarged, resulting in improvement of the transmittance. Besides, since the metal film in the same layer as that in which the gate electrode GE exists is used as the light shielding film M1, it is possible to narrow the spacing between the light sensing diode and the light shielding film and hence possible to improve the light shielding efficiency. As a result, the S/N ratio is improved and so is the read speed. Further, since the display area is separated from the image pickup area, it is possible to effect a high-definition and high-contrast image display.

### Fifth Embodiment

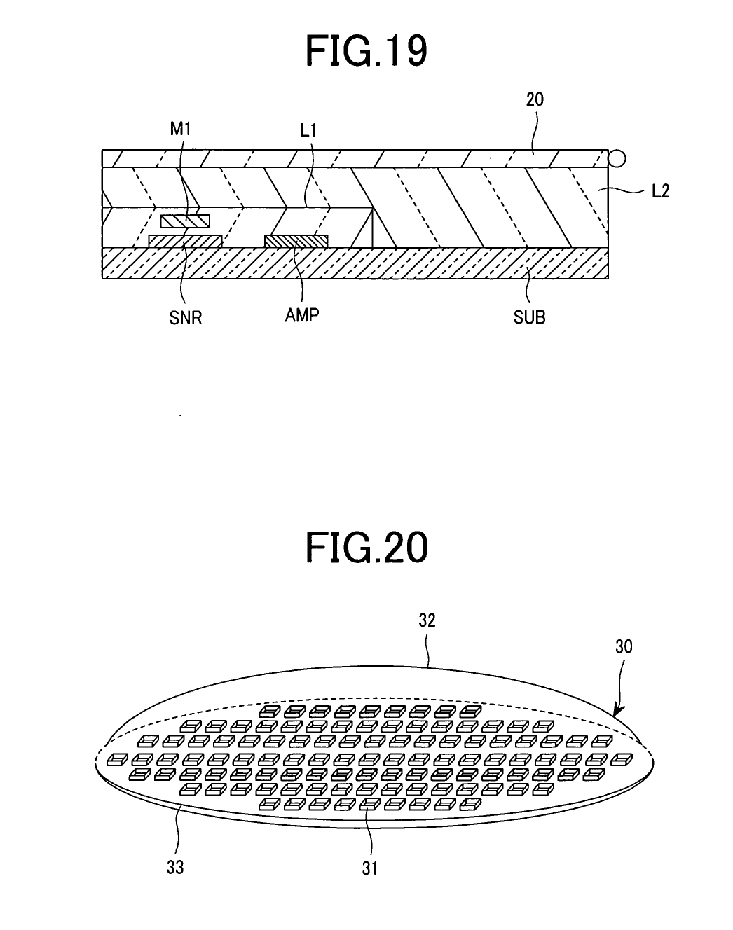

A combined image pickup-display device according to a fifth embodiment of the present invention is provided with a front light. A schematic structure of the fifth embodiment is the same as that shown in FIG. 15. A plan view of each pixel 2 of the present embodiment is the same as FIG. 16. FIG. 19 is a sectional view taken on line C-C′ of the pixel 2. The structure shown in FIG. 19 is almost the same as in the fourth embodiment and is different from the fourth embodiment in that it is provided with a front light 20. With respect to forming the front light, it suffices to use techniques adopted in the field of liquid crystal.

According to this fifth embodiment, since the area sensor is provided with the front light, it is possible to strengthen the light incident on the light sensing diode and hence the S/N ratio is improved. As a result, the read speed is improved.

### Sixth Embodiment

A combined image pickup-display device according to a sixth embodiment of the present invention is, as a whole, in the form of a transparent information lens having the shape of a convex lens. This sixth embodiment will be described below with reference to FIG. 20.

The device of this embodiment, indicated by reference numeral 30, is constructed using any of the combined image pickup-display devices described in the first to third embodiments. For example, it can be said that the device 30 is a transparent information lens having the shape of a convex lens and having a diameter of about 15 cm. Pixels 31 having both a read function and a display function are arranged planarly on a transparent substrate 33 whose lower surface is in the shape of a plane. The thickness of the transparent substrate 33 is about 5 mm, which is rather thick in order to maintain stability in use. The transparent area sensor having a display function is provided with a convex lens 32. Although the layout of pixels 31 in FIG. 20 is schematic, actually a large number of pixels are arranged at pitches of about 20 to 40 μm. According to this structure, a user can see a magnified printed matter of an electrically displayed image through the convex lens. The device of this embodiment can be utilized as a transparent sensor or an information lens in the sense of using the conventional optical convex lens. Since the device of this embodiment can be constructed in the same way as in the previous embodiments except that the convex lens function is provided, a detailed description thereof is here omitted.

In the combined image pickup-display devices of the above first to sixth embodiments, the light sensing diode may be formed using an amorphous silicon film, or the polycrystalline silicon TFT may be substituted by an organic semiconductor TFT, within the range capable of obtaining the effects of the present invention. Although in the above embodiments the light sensing diode is used for reading reflected light from a printed matter, an element capable of sensing other light. For example, there may be used a phototransistor to provide the light sensing element itself with an amplifying function, whereby reflected light from a printed matter can be read more efficiently.

The transparent substrate may be another insulating substrate such as quartz glass or plastic substrate, other than the glass substrate.

The crystallization of the amorphous silicon film may be done by the solid phase growth method. Alternatively, a polycrystalline silicon film may be formed by a hot-wire CVD method. Using another method, it is also possible to form a polycrystalline silicon film. For example, by subjecting laser light from a continuous oscillation solid-state laser to pulse modulation and scanning an amorphous silicon film under radiation of the laser light, thereby inducing crystal growth in the scanning direction, a polycrystalline Si film is formed, which is superior in crystallinity and having for example a crystal growth distance of 10 μm or more and a field effect mobility of about 500 cm²/Vs. As a result, it is possible to form a thin film light sensing diode of polycrystalline silicon having an excellent performance or a polycrystalline silicon TFT. By forming an area sensor or a circuit necessary for display with use of those elements, it becomes possible to, effectively and at a high speed, read image information, as well as perform recognition and conversion of image data, with respect to a printed matter. It also becomes possible to incorporate a larger number of functions into the device. Therefore, for example, not only the function of recognition, conversion and display of read data, but also the function of information terminals such as a processor, communication and a memory, can also be incorporated into the device.

In the combined image pickup-display devices described in the above first to sixth embodiments, the gate electrode may be formed using known electrode material such as Al, Mo, Ti, Ta, or W, or an alloy thereof. In this case, the metal film in the same layer as that in which the gate electrode exists may be used as a light shielding film, whereby it is possible to narrow the spacing between the light sensing diode and the light shielding film. Consequently, the light shielding efficiency is improved and so is the S/N ratio. The source-drain electrode may be formed using another known electrode material such as A1, Mo, or W without causing the transmittance to deteriorate.

In the combined image pickup-display device according to the present invention, a light transmitting area is provided within each pixel and the thin film light sensing diode and the TFT are each formed using a substantially transparent material, so that the device itself is transparent. Thus, the user can see the contents of the printed matter directly while the area sensor is placed on the printed matter. In order for the user to see the contents of the printed matter, it is preferable that the area of the light transmitting portion be 40% or more of the pixel area.

According to the present invention, since an image is read by, for example, designating a required image from above the device by the user only when required, it is possible to decrease the power consumption and hence possible to provide a combined image pickup-display device superior in portability.

Moreover, according to the present invention, the contents of a printed matter can be inspected directly while the user places the device on the printed matter. Further, since an image is read by, for example, designating a required image from above the device by the user only when required, it is possible to decrease the power consumption.

According to the present invention, as described above in detail, it is possible to provide a combined image pickup-display device that allows the user to see an object to be scanned even during image reading or a combined image pickup-display device that allows the user to see the contents of a printed matter even when the device is moved and that is superior in portability.

The following are principal modes of the present invention.
(1) A combined image pickup-display device including a plurality of optical sensors arranged planarly on a transparent substrate, the device being transparent and thus allowing the user to see the contents of an object to be scanned even during image reading.
(2) The combined image pickup-display device described in the above item (1), including on the transparent substrate a plurality of gate lines and a plurality of signal lines crossing the plural gate lines in a matrix shape, and wherein each of the optical sensors and a thin film transistor are provided in each of pixel regions surrounded by the gate lines and the signal lines, and a light shielding film of each of the optical sensors is formed by an electrode in the same layer as that in which a gate electrode of each of the thin film transistors exists.
(3) The combined image pickup-display device described in the above item (1), including on the transparent substrate a plurality of gate lines and a plurality of signal lines crossing the plural gate lines in a matrix shape, and wherein each of the optical sensors and a thin film transistor are provided in each of pixel regions surrounded by the gate lines and the signal lines, and a light shielding film of each of the optical sensors is formed by an electrode in the same layer as that in which a source-drain electrode of each of the thin film transistors exists.
(4) The combined image pickup-display device described in the above item (1), including on the transparent substrate a plurality of gate lines and a plurality of signal lines crossing the gate lines in a matrix shape, and wherein each of the optical sensors and a thin film transistor are provided in each of pixel regions surrounded by the gate lines and the signal lines, and a gate electrode and a source-drain electrode both constituting the thin film transistor are each formed to be transparent.
(5) The combined image pickup-display device described in the above item (1), including on the transparent substrate a plurality of gate lines and a plurality of signal lines crossing the gate lines in a matrix shape, and wherein each of the optical sensors and a thin film transistor are provided in each of pixel regions surrounded by the gate lines and the signal lines, and the gate lines and the signal lines are each formed to be transparent.
(6) The combined image pickup-display device described in the above item (1), including on the transparent substrate a plurality of gate lines and a plurality of signal lines crossing the gate lines in a matrix shape, and wherein each of the optical sensors, a thin film transistor and a light emitting element are provided in each of pixel regions surrounded by the gate lines and the signal lines.
(7) The combined image pickup-display device described in the above item (6), wherein a light shielding film of each of the optical sensors is formed by an electrode in the same layer as that in which an electrode which constitutes the light emitting element exists.
(8) The combined image pickup-display device described in the above item (6), wherein each of the optical sensors and the light emitting element are disposed in a vertically superimposed manner.
(9) The combined image pickup-display device described in the above item (6), including a light source for irradiating the object to be scanned when reading an image and means for shielding light reflected from the object to be scanned when displaying the image.
(10) The combined image pickup-display device described in the above item (9), wherein the light source is a back light and the light shielding means is constituted by a liquid crystal.
(11) A combined image pickup-display device including a plurality of optical sensors arranged planarly on a transparent substrate, the device being transparent and thus allowing the user to see an object to be scanned in the state where the device and the object to be scanned are superimposed with each other, the device further including means for designating an image pickup area, and wherein an image of the area designated by the means for designating an image pickup area is read as necessary.
(12) A combined image pickup-display device including a plurality of optical sensors arranged planarly on a transparent substrate, further including on a transparent substrate a plurality of gate lines and a plurality of signal lines crossing the gate lines in a matrix shape, and wherein each of the optical sensors and a light transmitting area are provided in each of pixel regions surrounded by the gate lines and the signal lines, and the contents of a scanning object can be seen through the light transmitting area even during image reading.
(13) The combined image pickup-display device described in the above item (12), wherein each of the optical sensors has a gate insulating film, an interlayer insulating film and a protective insulating film which covers a surface, in this order, formed on the substrate side, at least the interlayer insulating film being removed in the light transmitting area.
(14) A combined image pickup-display device including an image pickup device having a plurality of optical sensors arranged planarly on a transparent substrate and also including an image display device, the image pickup device and the image display device being provided in separate areas, the image pickup device being transparent and thus allowing the user to see the contents of an object to be scanned even during image reading.
(15) The combined image pickup-display device described in the above item (14), wherein the image pickup device has a front light as a light source to be used when reading an image.

Main reference numerals are shown below.

1 . . . transparent substrate, 2 . . . pixel, 3 . . . integrated circuit, 4 . . . printed matter, 5 . . . touch pen, 6 . . . image to be read, 7 . . . image read area, 8 . . . image pickup area, 9 . . . display area, SUB . . . transparent substrate, SNR . . . light sensing diode, AMP . . . signal conversion and amplifying circuit, LED . . . light emitting element, OPN . . . light transmitting area, SW1 . . . TFT circuit for driving an organic light emitting diode, SW2 . . . TFT circuit for driving a liquid crystal, L1 . . . interlayer insulating film, L2 . . . protective insulating film, L3 . . . buffer layer, L4 . . . gate insulating film, L5 . . . interlayer insulating film formed of silicon oxide, L6 . . . interlayer insulating film formed of silicon nitride, L7 . . . organic light emitting material, M1 . . . light shielding film, M2 . . . lower electrode of the light emitting element, M3 . . . upper electrode of the light emitting element, GE . . . gate electrode, SD . . . source-drain electrode, PS . . . polycrystalline silicon film, R1 . . . source diffusion layer, R2 . . . drain diffusion layer, R3 . . . cathode layer, R4 . . . anode layer, R5 . . . intrinsic region, LT1 . . . light source, LT2 . . . light conducting plate, LC . . . liquid crystal, 20 . . . front light, 30 . . . transparent substrate, 31 . . . pixel, 32 . . . convex lens, 100 . . . arrival of reflected light at the light sensing diode, 101 . . . generation of light-induced carriers, 102 . . . selection of a pixel to be read, 103 . . . amplification of light-induced carriers, 104 . . . acquisition of two-dimensional image information, 105 . . . recognition and conversion of data, 106 . . . shading reflection light, 107 . . . image display

### INDUSTRIAL APPLICABILITY

The present invention can provide an image display device capable of performing both image pickup and image display.

1. A combined image pickup-display device comprising at least a light transmitting substrate, a plurality of pixels arranged on a first surface of said light transmitting substrate, and a display section, wherein:
each of said pixels has at least a photoelectric conversion element portion and a light transmitting area;
an object to be scanned is disposed on a second surface side of said light transmitting substrate;
said photoelectric conversion element portion has a light shielding film on the side opposite to said light transmitting substrate;
said photoelectric conversion element portion detects light outputted from the second surface side of said light transmitting substrate; and
the object to be scanned is visible from the first surface side of said light transmitting substrate even when the object is read by the device.

2. The device of claim 1, wherein each display region in said display section is provided within said each pixel.

3. The device of claim 1, wherein said each display region in said display section is provided in areas different from said pixels.

4. The device of claim 1, further including on the first surface of said light transmitting substrate a plurality of gate lines and a plurality of signal lines arranged so as to cross said gate lines, wherein:
an area surrounded by a pair of said gate lines and a pair of said signal lines is an area of each of said pixels;
said photoelectric conversion element portion provided within the pixel area is a thin film photoelectric conversion element formed on the first surface of said light transmitting substrate; and
an electronic circuit section having a thin film transistor is provided on the first surface of said light transmitting substrate.

5. The device of claim 1, wherein said light shielding film is formed in a conductor layer same as a layer in which a gate electrode of the thin film transistor exists, the gate electrode being formed on the first surface of said light transmitting substrate.

6. The device of claim 1, wherein said light shielding film is formed in a conductor layer same as a layer in which a source-drain electrode of the thin film transistor exists, the source-drain electrode being formed on the first surface of said light transmitting substrate.

7. The device of claim 1, wherein a gate electrode and a source-drain electrode of a thin film transistor formed on the first surface of said light transmitting substrate are transparent electrodes.

8. The device of claim 1, wherein gate lines and signal lines are formed of transparent electrodes.

9. The device of claim 1, wherein said display section is a light emitting element.

10. The device of claim 9, wherein said light shielding film is formed in a conductor layer same as a layer in which one electrode having a light emitting element exists.

11. The device of claim 1, comprising at least said photoelectric conversion element portion and an electronic circuit portion having a thin film transistor on the first surface of said light transmitting substrate, wherein
a display portion is disposed in an upper part of said light shielding film on the side opposite to said light transmitting substrate.

12. The device of claim 11, wherein a second light transmitting substrate is disposed over said display portion.

13. The device of claim 1, further comprising:
a light source for irradiating said object to be scanned when reading an image; and
means for shielding light reflected from the object to be scanned when displaying the image.

14. The device of claim 13, wherein said light source is a back light and said means for shielding light is formed with a liquid crystal.

15. The device of claim 1, further comprising means for designating an image pickup area.

16. The device of claim 1, wherein at least an interlayer insulating film is removed in said light transmitting area.

17. The device of claim 3, wherein a front light is provided.
